(19) United States
(12) Patent Application Publication
(10) Pub. No.: US 2002/0168823 A1
(43) Pub. Date: Nov. 14, 2002

(54) Method for fabricating recessed lightly doped drain field effect transistors

(76) Inventor: Horn-Huei Tseng, Hsinchu (TW)

Correspondence Address: Richard E. Fichter, BACON & THOMAS, PLLC, Fourth Floor, 625 Slaters Lane, Alexandria, VA, 22314, US

(21) Appl. No.: 09/850,096

(22) Filed: May 8, 2001

(51) Int. Cl. H01L 21/336

(52) U.S. Cl. 438/282

(57) ABSTRACT

The present invention provides a method for fabricating recessed lightly doped drain(LDD) field-effect transistors, comprising the steps of: providing a substrate and forming a sacrificial layer and a first dielectric layer on said substrate; patterning said sacrificial layer and said first dielectric layer so as to form a window; depositing a doped dielectric layer, wherein said doped dielectric layer is doped with dopants; etching back said doped dielectric layer so as to form spacers; forming a gate dielectric layer and lightly doped regions; depositing a conductor filling said window; removing said first dielectric layer; and heavily doping ions so as to form heavily doped regions. In this manner, a recessed lightly doped drain field-effect transistor is completed.

### BACKGROUND OF THE INVENTION

1. Field of the Invention

The present invention generally relates to a method for fabricating recessed field-effect transistors, and more particular, to a method for fabricating lightly doped drain(LDD) field-effect transistors having an ultra-short gate, high integrity, and good reliability.

2. Description of the Prior Art

The metal-oxide-semiconductor field-effect transistor (MOSFET) has now become the most important device in very/ultra large scale integrated circuits (VLSIs/ULSIs). In addition to the MOS structure, there are provided a source electrode, a drain electrode and a gate electrode on the top of the MOS structure. Complementary MOS (CMOS) circuits have been widely used in logic applications such as microprocessors, micro-controllers, etc. Furthermore,the hot-carrier effect can be improved by add “lightly doped drain(LDD)”, so that the reliability of the device can be improved.

However, with response to the requirement of simplified processing and improved reliability for the industry, a new method for fabricating field-effect transistors has been disclosed. FIG. 1A to FIG. 1E are schematic diagrams illustrating the steps of a method for fabricating field-effect transistors. As shown in FIG. 1A, a gate oxide layer 20 is formed on a semiconductor substrate 10 and then a polysilicon layer 30 and a conductor layer 40 are deposited and defined, wherein the conductor layer 40 is composed of conducting materials such as poly-silicon, silicide and metal to be a gate electrode. The main difference from the prior arts is that a doped dielectric layer 50 is deposited on the conductor layer 40 and the gate oxide layer 20. The doped dielectric layer 50 is doped with the required p-type or n-type dopant, as shown in FIG. 1B.

Then, the doped dielectric layer 50 is etched back to form spacers 501, more particularly, doped spacers, as shown in FIG. 1C.

During the subsequent thermal process, the impurities in the spacers 501 may thermally diffuse into the substrate 10 and form lightly doped regions 60, as shown in FIG. 1D.

Finally, heavily doped regions 70 are formed by heavily doping ions into the substrate so as to complete a field-effect transistor, as shown in FIG. 1E.

Even though the fore-mentioned method is more progressive than the conventional ones, however, there still exists a problem in that it is more difficult to etch conducting materials such as poly-silicon and metal than dielectric materials. In other words, on the level of finer feature size, it remains unhelpful in down-sizing.

Therefore, the present invention discloses a method for fabricating novel recessed lightly doped drain field-effect transistors, wherein spacers are formed inside recessed region and the space for defining the spacers is greatly reduced, leading to higher integrity. In this method, the gate length of the lightly doped drain(LDD) field-effect transistor can be shorter than the limited resolution of photolithography, and the process reliability can be improved because dielectric material instead of poly-silicon or metal is etched.

### SUMMARY OF THE INVENTION

It is the primary object of the present invention to provide a method for fabricating recessed field-effect transistors, wherein the gate window is significantly narrowed and the space for defining the spacers is greatly reduced.

It is another object of the present invention to provide a method for fabricating recessed field-effect transistors that overcomes the fore-mentioned problems and leads to higher integrity.

In order to achieve the foregoing objects, the present invention provides a method for fabricating recessed field-effect transistors, comprising the steps of: providing a substrate and forming a sacrificial layer and a first dielectric layer on said substrate; patterning said sacrificial layer and said first dielectric layer so as to form a window; depositing a doped dielectric layer, wherein said doped dielectric layer is doped with dopants; etching back said doped dielectric layer so as to form spacers; forming a gate dielectric layer and lightly doped regions; depositing a conductor filling said window; removing said first dielectric layer; and heavily doping ions so as to form heavily doped regions.

The major difference is that a gate dielectric layer and a conductor layer are formed prior to the definition of spacers in the prior arts while a gate window is defined prior to the formation of spacers in the present invention. Consequently, the gate window is significantly narrowed and the space for defining the spacers is greatly reduced, leading to higher integrity and lower fabrication cost.

### BRIEF DESCRIPTION OF THE DRAWINGS

The objects, spirits and advantages of the preferred embodiments of the present invention will be readily understood by the accompanying drawings and detailed descriptions, wherein:

FIG. 1A to FIG. 1E are schematic diagrams illustrating the steps of a method for fabricating field-effect transistors in the prior art;

FIG. 2A is a schematic diagram illustrating the step of forming a sacrificial layer and a first dielectric layer on a substrate in accordance with the first and the second embodiments of the present invention;

FIG. 2B is a schematic diagram illustrating the step of forming a window and depositing a doped dielectric layer in accordance with the first and the second embodiments of the present invention;

FIG. 2C is a schematic diagram illustrating the step of forming doped spacers in accordance with the first and the second embodiments of the present invention;

FIG. 2D is a schematic diagram illustrating the step of forming a gate dielectric layer and lightly doped regions in accordance with the first and the second embodiments of the present invention;

FIG. 2E is a schematic diagram illustrating the step of depositing a conductor in accordance with the first and the second embodiments of the present invention; and

FIG. 2F is a schematic diagram illustrating the step of forming heavily doped regions in accordance with the first and the second embodiments of the present invention.

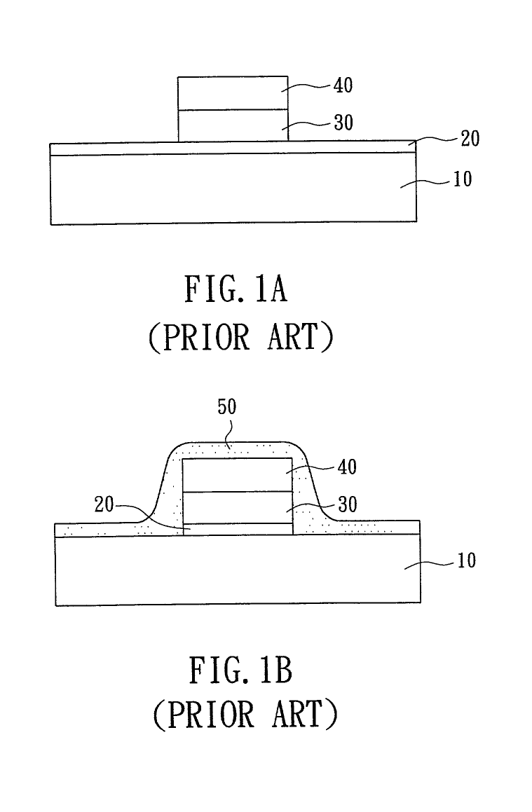

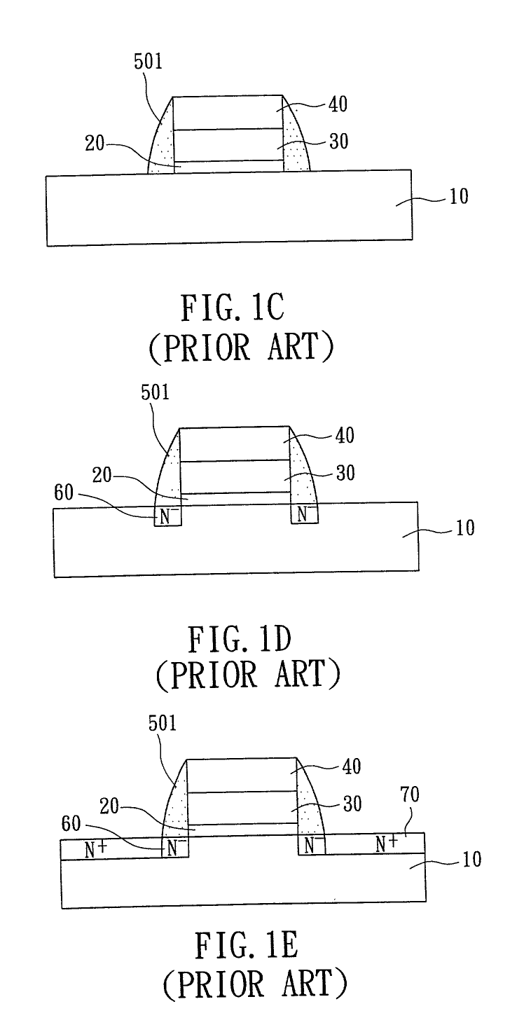

### DETAILED DESCRIPTION OF THE INVENTION

[The First Embodiment]

The present invention is described with reference to a first embodiment wherein a recessed field-effect transistor is formed on a p-type substrate.

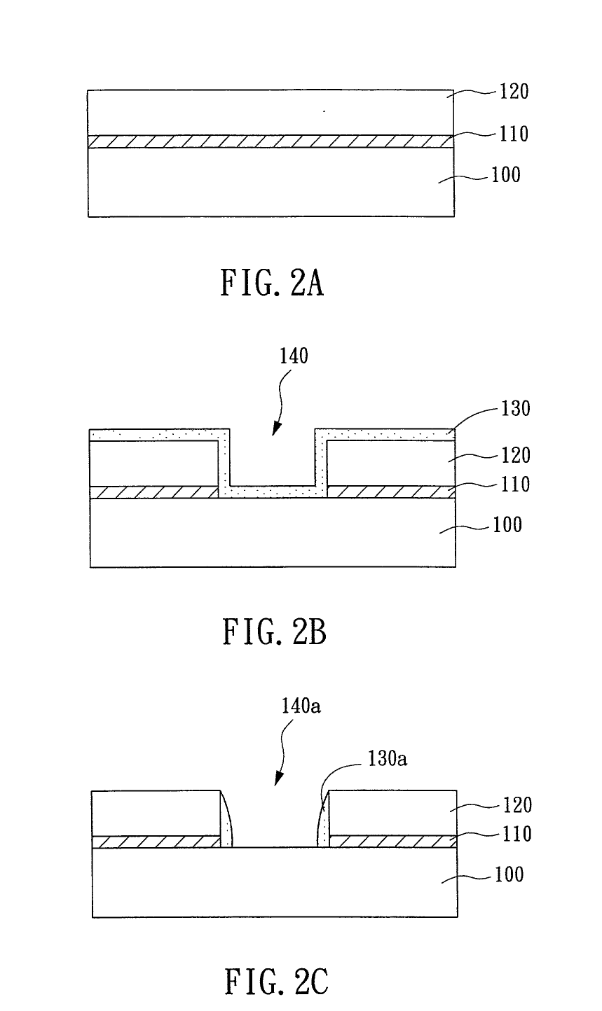

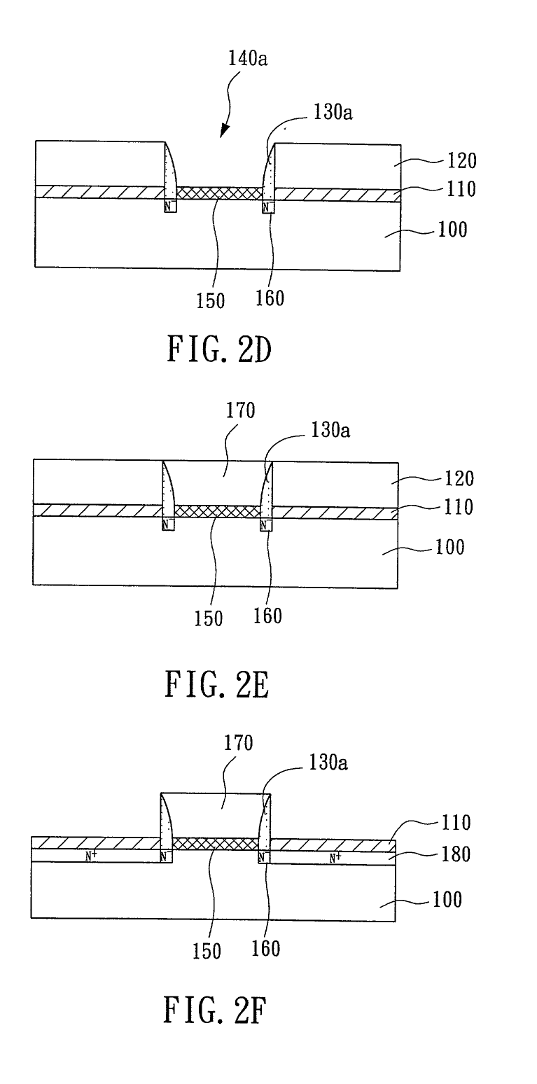

Please refer to FIG. 2A, wherein there is provided a p-type semiconductor substrate 100. On the p-type semiconductor substrate 100, a sacrificial layer 110 and a first dielectric layer 120 are formed. The sacrificial layer 110 can be formed by forming a silicon oxide layer of 50˜500 Å in thickness on the semiconductor substrate 100 by thermal oxidation. The first dielectric layer 120 can be formed by depositing a silicon oxide layer by chemical vapor-phase deposition (CVD).

The present invention is characterized in that the sacrificial layer 110 and the first dielectric layer 120 are patterned so as to form a window 140, wherein the window 140 is 0.1˜0.5 μm in width. Later, as shown in FIG. 2B, a doped dielectric layer 130 is deposited, and the doped dielectric layer 130 is an n-type doped silicon dioxide layer, wherein the dopant is solid-state As, solid- state P, or AsH₃ gas.

Moreover, as shown in FIG. 2C, the doped dielectric layer 130 is etched back so as to form doped spacers 130a in the window 140a.

Thermal oxidation is then performed to form a gate dielectric layer 150. In such a high temperature environment, the doped spacers 130a serve as a dopant source and form lightly doped regions 160 during the process of forming the gate dielectric layer 150, as shown in FIG. 2D.

Please further refer to FIG. 2E, a conductor layer 170 is deposited and fills the window 140a, wherein the conductor layer 170 is composed of one of poly-silicon, silicide and metal. Planarization is performed by removing the residual conductor 170 outside the window 140a by chemical

Finally, the first dielectric layer 120 is removed and then the n-type dopant is heavily doped into the substrate 100 so as to form heavily doped regions serving as the source and the drain 180, as shown in FIG. 2F. In this manner, a recessed field-effect transistor is completed.

[The Second Embodiment]

Similarly, the present invention is described with reference to a second embodiment wherein a recessed field-effect transistor is formed on an n-type substrate. The present embodiment uses the same symbols as in the first embodiment.

Please refer to FIG. 2A, wherein there is provided an n-type semiconductor substrate 100. On the n-type semiconductor substrate 100, a sacrificial layer 110 and a first dielectric layer 120 are formed. The sacrificial layer 110 can be formed by forming a silicon oxide layer of 50˜500 Å in thickness on the semiconductor substrate 100 by thermal oxidation. The first dielectric layer 120 can be formed by depositing a silicon oxide layer by chemical vapor-phase deposition (CVD).

The present invention is characterized in that the sacrificial layer 110 and the first dielectric layer 120 are patterned so as to form a window 140, wherein the window 140 is 0.1˜0.5 μm in width. Later, as shown in FIG. 2B, a doped dielectric layer 130 is deposited, and the doped dielectric layer 130 is a p-type doped silicon dioxide layer, wherein the dopant is BF₃.

Moreover, as shown in FIG. 2C, the doped dielectric layer 130 is etched back so as to form doped spacers 130a in the window 140a.

Thermal oxidation is then performed to form a gate dielectric layer 150. In such a high temperature environment, the doped spacers 130a serve as a dopant source and form lightly doped regions 160 during the process of forming the gate dielectric layer 150, as shown in FIG. 2D.

Please further refer to FIG. 2E, a conductor layer 170 is deposited and fills the window 140a, wherein the conductor layer 170 is composed of one of poly-silicon, silicide and metal. Planarization is performed by removing the residual conductor 170 outside the window 140a by chemical mechanical polishing (CMP).

Finally, the first dielectric layer 120 is removed and then the p-type dopant is heavily doped into the substrate 100 so as to form heavily doped regions serving as the source and the drain 180, as shown in FIG. 2F. In this manner, a recessed field-effect transistor is completed.

As discussed so far, in accordance with the present invention, there is provided a method for fabricating recessed field-effect transistors, which is different from the prior arts in that a gate dielectric layer and a conductor layer are formed prior to the definition of spacers in the prior arts while a gate window is defined prior to the formation of spacers in the present invention. Obviously, the gate window is significantly narrowed and the space for defining the spacers is greatly reduced, leading to higher integrity and lower fabrication cost. Consequently, the present invention has been examined to be progressive and has great potential in commercial applications.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for fabricating recessed lightly doped drain(LDD) field-effect transistors, comprising the steps of:
providing a p-type silicon semiconductor substrate and forming a sacrificial layer and a first dielectric layer on said substrate;
patterning said first dielectric layer and sacrificial layer so as to form a window;
depositing a conformal doped dielectric layer, wherein said doped dielectric layer is doped with n-type dopants;
etching back said doped dielectric layer so as to form doped spacers;
forming a gate dielectric layer;
depositing a conductor filling said window;
removing said first dielectric layer; and
heavily doping n-type ions so as to form heavily doped source/drain regions.

2. The method for fabricating recessed lightly doped drain field-effect transistors as recited in claim 1, wherein said first dielectric layer is silicon nitride and sacrificial layer is a silicon dioxide.

3. The method for fabricating recessed lightly doped drain field-effect transistors as recited in claim 1, wherein said sacrificial layer is 50˜500 Å in thickness.

4. The method for fabricating recessed lightly doped drain field-effect transistors as recited in claim 2, wherein said first dielectric layer is 1000˜3500 Å in thickness.

5. The method for fabricating recessed lightly doped drain field-effect transistors as recited in claim 1, wherein said window is 0.05˜0.5 μm in width.

6. The method for fabricating recessed lightly doped drain field-effect transistors as recited in claim l, wherein said doped dielectric layer is an n-type doped silicon dioxide layer.

7. The method for fabricating recessed lightly doped drain field-effect transistors as recited in claim 1, wherein said gate dielectric layer is formed by thermal oxidized said silicon substrate.

8. The method for fabricating recessed lightly doped drain field-effect transistors as recited in claim 1, wherein said gate dielectric layer is formed by deposited dielectric layer.

9. The method for fabricating recessed lightly doped drain field-effect transistors as recited in claim 1, wherein the dopant source of said lightly doped regions is said doped dielectric layer.

10. The method for fabricating recessed lightly doped drain field-effect transistors as recited in claim 1, wherein said, wherein said conductor is one of poly-silicon, metal silicide, α-silicon, and metal.

11. The method for fabricating recessed lightly doped drain field-effect transistors as recited in claim 1, wherein said step of depositing a conductor filling said window further comprises a step of removing said residual conductor outside said window by chemical mechanical polishing (CMP).

12. A method for fabricating recessed lightly doped drain field-effect transistors, comprising the steps of:
providing an n-type silicon semiconductor substrate and forming a sacrificial layer and a first dielectric layer on said substrate;
patterning said first dielectric layer and sacrificial layer so as to form a window;
depositing a conformal doped dielectric layer, wherein said doped dielectric layer is doped with p-type dopants;
etching back said doped dielectric layer so as to form doped spacers;
forming a gate dielectric layer;
depositing a conductor filling said window;
removing said first dielectric layer; and
heavily doping p-type ions so as to form heavily doped source/drain regions.

13. The method for fabricating recessed lightly doped drain field-effect transistors as recited in claim 12, wherein said first dielectric layer is silicon nitride and sacrificial layer is a silicon dioxide.

14. The method for fabricating recessed lightly doped drain field-effect transistors as recited in claim 12, wherein said sacrificial layer is 50˜500 Å in thickness.

15. The method for fabricating recessed lightly doped drain field-effect transistors as recited in claim 13, wherein said first dielectric layer is 1000˜3500 Å in thickness.

16. The method for fabricating recessed lightly doped drain field-effect transistors as recited in claim 12, wherein said window is 0.05˜0.5 μm in width.

17. The method for fabricating recessed lightly doped drain field-effect transistors as recited in claim 12, wherein said doped dielectric layer is an n-type doped silicon dioxide layer.

18. The method for fabricating recessed lightly doped drain field-effect transistors as recited in claim 12, wherein said gate dielectric layer is formed by thermal oxidized said silicon substrate.

19. The method for fabricating recessed lightly doped drain field-effect transistors as recited in claim 12, wherein said gate dielectric layer is formed by deposited dielectric layer.

20. The method for fabricating recessed lightly doped drain field-effect transistors as recited in claim 12, wherein the dopant source of said lightly doped regions is said doped dielectric layer.

21. The method for fabricating recessed lightly doped drain field-effect transistors as recited in claim 12, wherein said, wherein said conductor is one of poly-silicon, metal silicide, α-silicon, and metal.

22. The method for fabricating recessed lightly doped drain field-effect transistors as recited in claim 12, wherein said step of depositing a conductor filling said window further comprises a step of removing said residual conductor outside said window by chemical mechanical polishing (CMP).

23. A structure of recessed lightly doped drain (LDD) field-effect transistors, including:
a silicon semiconductor substrate having a gate electrode;
a gate dielectric layer on the bottom of said gate electrode;
two recessed doped dielectric spacers structured two sides of said gate electrode;
improvements of said structure comprising: said two recessed doped dielectric spacers combine with said gate electrode to be as a rectangular from front view.

24. The method for fabricating recessed lightly doped drain field-effect transistors as recited in claim 23, wherein said gate electrode is 0.05˜0.5 μm in width.

25. The method for fabricating recessed lightly doped drain field-effect transistors as recited in claim 23, wherein said gate dielectric layer is formed by thermal oxidized said silicon substrate.

26. The method for fabricating recessed lightly doped drain field-effect transistors as recited in claim 23, wherein said gate dielectric layer is formed by deposited dielectric layer.
